(19) United States
(12) Patent Application Publication
(10) Pub. No.: US 2006/0006965 A1
(43) Pub. Date: Jan. 12, 2006

(54) RF filter and method for fabricating the same

(75) Inventor: Motonori Ishii, Osaka (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/174,556

(22) Filed: Jul. 6, 2005

(30) Foreign Application Priority Data
Jul. 6, 2004 (JP) 2004-199166

(51) Int. Cl. H03H 9/58; H03H 9/56

(52) U.S. Cl. 333/191

(57) ABSTRACT

An RF filter includes: one or more first piezoelectric resonators each of which is held on a principal surface of a substrate and is constituted by a first piezoelectric film and opposed first upper and lower electrodes provided on the upper and lower faces of the first piezoelectric film, respectively; and one or more second piezoelectric resonators each of which is held on the principal surface of the substrate, is constituted by a second piezoelectric film and opposed second upper and lower electrodes provided on the upper and lower faces of the second piezoelectric film, respectively, and has a resonance frequency different from that of each of the first piezoelectric resonators. At least one of the first upper and lower electrodes is made of a first electrode material and at least one of the second upper and lower electrodes is made of a second electrode material.

### CROSS-REFERENCE TO RELATED APPLICATION

This application claims priority under 35 U.S.C. §119 on Patent Application No. 2004-199166 filed in Japan on Jul. 6, 2004, the entire contents of which are hereby incorporated by reference. The entire contents of Patent Application No. 2005-193621 filed in Japan on Jul. 1, 2005 are also incorporated by reference.

### BACKGROUND OF THE INVENTION

The present invention relates to RF filters using piezoelectric resonators and methods for fabricating the RF filters.

With recent global proliferation of cellular phones, the number of cellular phones in use has been increasing in an accelerated pace. The cellular phones need to process RF signals with different frequencies, and it is generally necessary to remove RF signals with frequencies other than a desired frequency. In a terminal, for example, it is always necessary to remove RF signals other than signals with a target frequency for a circuit called a front end that receives signals with frequencies transmitted from a base station. For a circuit that converts a received signal into a signal with an intermediate frequency for use in signal processing inside the terminal, signals with frequencies other than the intermediate frequency need to be removed. To remove such RF signals with unwanted frequencies and pass only RF signals with a desired frequency, components called RF filters are generally used.

RF filters are required to minimize a loss in passing a signal with a desired frequency and to greatly attenuate signals with the other frequencies. For these requirements, frequency characteristics of the RF filters are important in preventing passage of signals with frequencies other than the desired frequency and also in preventing attenuation of signals with the desired frequency. In particular, the frequencies of RF signals transmitted from a terminal to a base station and the frequencies of RF signals transmitted from the base station to the terminal are generally close to each other, and thus a frequency characteristic strictly as designed is needed.

One of the components constituting such filters is a resonator. To obtain a desired frequency characteristic of an RF filter, it is essential to adjust the resonance frequency of a resonator for use in the RF filter to a value precisely as designed. To reduce the size of filters and enhance the performance thereof, SAW resonators using surface acoustic waves and piezoelectric resonators using bulk acoustic waves have been used for the filters in recent years.

To obtain an as-designed resonance frequency of a piezoelectric resonator, a piezoelectric film, an upper electrode and a lower electrode need to be accurately formed to have a total thickness as designed. However, it is generally difficult to form a thin film having a thickness precisely as designed. Therefore, the piezoelectric resonator needs adjustment for precisely obtaining a desired resonance frequency after the formation of the resonator.

For example, in Japanese Unexamined Patent Publication (Kokai) No. 2001-196883, an upper electrode is formed to have a thickness larger than that of a lower electrode, and then the thickness of the upper electrode is reduced with the resonance frequency measured, thereby adjusting the resonance frequency to a desired value.

In U.S. Pat. No. 6,507,983, a deviation in thickness of a substrate on which a piezoelectric resonator is formed is measured and conditions for vapor deposition of a lower electrode are determined. Then, under these conditions, a lower electrode is formed by vapor deposition, thereby determining the thickness of the lower electrode and adjusting the resonance frequency to a desired value.

However, adjustment of the resonance frequency of a piezoelectric resonator for obtaining a desired frequency characteristic of an RF filter by the conventional methods has the following problem.

An RF filter is constituted by at least two piezoelectric resonators having different resonance frequencies. Therefore, a plurality of piezoelectric resonators formed on a substrate are generally adjusted to have at least two different resonance frequencies. However, the conventional methods only enable all the piezoelectric resonators formed on a substrate to have the same resonance frequency. Accordingly, adjustment of the piezoelectric resonators by the conventional methods has a problem in which the adjustment process is very complicated.

For example, some of the piezoelectric resonators formed on a substrate are masked and the resonance frequencies of the other piezoelectric resonators are adjusted. Then, the piezoelectric resonators whose resonance frequencies have been adjusted are masked and the mask covering the piezoelectric resonators whose resonance frequencies have not been adjusted yet is removed for adjustment of the resonance frequencies. In this case, the number of processes using a mask increases.

### SUMMARY OF THE INVENTION

It is therefore an object of the present invention to provide an RF filter in which piezoelectric resonators formed on a substrate are adjusted to have different resonance frequencies without a complicated process and which has a constant frequency characteristic.

In order to achieve this object, an RF filter according to the present invention includes two types of resonators, and at least one of an upper electrode and a lower electrode of a resonator of one type is made of a material different from a material constituting an upper electrode or a lower electrode of a resonator of the other type.

Specifically, a first RF filter according to the present invention includes: a substrate having a principal surface; one or more first piezoelectric resonators, each of the first piezoelectric resonators being held on the principal surface of the substrate and being constituted by a first piezoelectric film, a first upper electrode and a first lower electrode, the first upper electrode and the first lower electrode being opposed to each other and provided on the upper face and the lower face of the first piezoelectric film, respectively; and one or more second piezoelectric resonators, each of the second piezoelectric resonators being held on the principal surface of the substrate, being constituted by a second piezoelectric film, a second upper electrode and a second lower electrode, and having a resonance frequency different from that of each of the first piezoelectric resonators, the second upper electrode and the second lower electrode being opposed to each other and provided on the upper face and the lower face of the second piezoelectric film, respectively, wherein at least one of the first upper electrode and the first lower electrode is made of a first electrode material and at least one of the second upper electrode and the second lower electrode is made of a second electrode material.

In the first RF filter, the resonance frequency of the first piezoelectric resonator is adjusted by etching the first electrode material and the resonance frequency of the second piezoelectric resonator is adjusted by etching the second electrode material. Accordingly, the resonance frequencies of the first and second piezoelectric resonators are easily adjusted to different values, so that an RF filter having a constant frequency characteristic can be achieved.

Preferably, in the first RF filter, the first electrode material is etched with a first etchant and has etching resistance to a second etchant that allows etching of the second electrode material. With this configuration, in adjusting the resonance frequency of the second piezoelectric resonator using the second etchant, variation of the resonance frequency of the first piezoelectric resonator is prevented without fail. Accordingly, the RF filter can be adjusted without increase in the number of processes for forming a mask.

In this case, the first electrode material is preferably platinum, and the second electrode material is preferably gold.

In that case, the second electrode material preferably has etching resistance to the first etchant. The first electrode material is preferably gold, and the second electrode material is preferably titanium or aluminum.

The first RF filter preferably further includes at least one of a first additional film and a second additional film, the first additional film being formed on at least one of the upper face of the first upper electrode and the lower face of the first lower electrode, the second material being formed on at least one of the upper face of the second upper electrode and the lower face of the second lower electrode. With this configuration, the resonance frequency of at least one of the first and second piezoelectric resonators is adjusted by etching an additional film, so that the resonance frequency of a piezoelectric resonator is adjusted more easily.

Preferably, in the first RF filter, one of the second upper electrode and the second lower electrode is electrically connected to the first upper electrode or the first lower electrode to form a basic unit of a ladder resonator in which the other of the second upper electrode and the second lower electrode is grounded, and the first electrode material and the second electrode material are selected so that an insertion loss of each of the first piezoelectric resonators is smaller than that of each of the second piezoelectric resonators. With this configuration, an insertion loss of the RF filter is reduced.

In this case, an inductor is preferably electrically connected between the second upper electrode or the second lower electrode and ground.

Preferably, the first RF filter further includes a first input/output terminal, a second input/output terminal, a third input/output terminal and a fourth input/output terminal, wherein the number of the first resonators is two, one of the two first resonators is electrically connected between the first input/output terminal and the second input/output terminal, the other first resonator is electrically connected between the third input/output terminal and the fourth input/output terminal, the number of the second resonators is two, one of the two second resonators is electrically connected between the first input/output terminal and the fourth input/output terminal, the other second resonator is electrically connected between the third input/output terminal and the second input/output terminal, and the first electrode material and the second electrode material are selected so that an insertion loss of each of the first resonators is smaller than that of each of the second resonators. With this configuration, an insertion loss of the RF filter is reduced and, in addition, an RF filter having parallel inputs and parallel outputs is implemented.

A second RF filter according to the present invention includes: a substrate having a principal surface; one or more first piezoelectric resonators, each of the first piezoelectric resonators being held on the principal surface of the substrate and being constituted by a first piezoelectric film, a first upper electrode and a first lower electrode, the first upper electrode and the first lower electrode being opposed to each other and provided on the upper face and the lower face of the first piezoelectric film, respectively; one or more second piezoelectric resonators, each of the second piezoelectric resonators being held on the principal surface of the substrate, being constituted by a second piezoelectric film, a second upper electrode and a second lower electrode, and having a resonance frequency different from that of each of the first piezoelectric resonators, the second upper electrode and the second lower electrode being opposed to each other and provided on the upper face and the lower face of the second piezoelectric film, respectively; at least one of a first upper-electrode additional film and a first lower-electrode additional film, the first upper-electrode additional film being formed on the upper face of the first upper electrode, the first lower-electrode additional film being formed on the lower face of the first lower electrode; and at least one of a second upper-electrode additional film and a second lower-electrode additional film, the second upper-electrode additional film being formed on the upper face of the second upper electrode, the second lower-electrode additional film being formed on the lower face of the second lower electrode, wherein at least one of the first upper-electrode additional film and the first lower-electrode additional film is made of a first additional-film material, and at least one of the second upper-electrode additional film and the second lower-electrode additional film is made of a second additional-film material.

In the second RF filter, the resonance frequencies of the first and second piezoelectric resonators are respectively adjusted by etching two films made of different materials. Accordingly, the resonance frequencies of the first and second piezoelectric resonators are easily adjusted to different values. In addition, insulating films can be used as additional films, resulting in the advantage that the additional films are easily formed and etched.

Preferably, in the second RF filter, the first additional-film material is etched with a first etchant and has etching resistance to a second etchant that allows etching of the second additional-film material. In this case, the first additional-film material is preferably platinum, and the second additional-film material is preferably gold. With this configuration, the resonance frequency of the second piezoelectric resonator can be adjusted without variation of the resonance frequency of the first piezoelectric resonator.

In the second RF filter, the second additional-film material preferably has etching resistance to the first etchant. In this case, the first additional-film material is preferably silicon nitride, and the second additional-film material is preferably silicon oxide. The first additional-film material is preferably gold, and the second additional-film material is preferably titanium or aluminum.

Preferably, in the second RF filter, one of the second upper electrode and the second lower electrode is electrically connected to the first upper electrode or the first lower electrode to form a basic unit of a ladder resonator in which the other of the second upper electrode and the second lower electrode is grounded, and the first additional-film material and the second additional-film material are selected so that an insertion loss of each of the first piezoelectric resonators is smaller than that of each of the second piezoelectric resonators.

In this case, an inductor is preferably electrically connected between the second upper electrode or the second lower electrode and ground.

Preferably, the second RF filter further includes a first input/output terminal, a second input/output terminal, a third input/output terminal and a fourth input/output terminal, wherein the number of the first resonators is two, one of the two first resonators is electrically connected between the first input/output terminal and the second input/output terminal, the other first resonator is electrically connected between the third input/output terminal and the fourth input/output terminal, the number of the second resonators is two, one of the two second resonators is electrically connected between the first input/output terminal and the fourth input/output terminal, the other second resonator is electrically connected between the third input/output terminal and the second input/output terminal, and the first additional-film material and the second additional-film material are selected so that an insertion loss of each of the first resonators is smaller than that of each of the second resonators.

A first method for fabricating an RF filter according to the present invention includes the steps of: holding a first piezoelectric resonator and a second piezoelectric resonator on a principal surface of a substrate, the first piezoelectric resonator being constituted by a first piezoelectric film, a first upper electrode and a first lower electrode, the first upper electrode and the first lower electrode being opposed to each other and provided on the upper face and the lower face of the first piezoelectric film, respectively, the second piezoelectric resonator being constituted by a second piezoelectric film, a second upper electrode and a second lower electrode, the second upper electrode and the second lower electrode being opposed to each other and provided on the upper face and the lower face of the second piezoelectric film, respectively; adjusting the resonance frequency of the first piezoelectric resonator by using a first etchant that allows etching of at least one of the first upper electrode and the first lower electrode; and adjusting the resonance frequency of the second piezoelectric resonator by using a second etchant that allows etching of at least one of the second upper electrode and the second lower electrode.

With the first method for fabricating an RF filter, the resonance frequency of the second piezoelectric resonator can be adjusted without variation of the resonance frequency of the first piezoelectric resonator. Accordingly, complicated masks are unnecessary, so that an RF filter exhibiting a constant frequency characteristic can be easily obtained.

In the first method, at least one of the first upper electrode and the first lower electrode is preferably made of gold, at least one of the second upper electrode and the second lower electrode is preferably made of titanium or aluminum, the first etchant is preferably an iodine-based etchant, and the second etchant is preferably a hydrofluoric acid-based etchant. With this configuration, the resonance frequency of the first piezoelectric resonator is adjusted without variation of the resonance frequency of the second piezoelectric resonator and the resonance frequency of the second piezoelectric resonator is also adjusted without variation of the resonance frequency of the first piezoelectric resonator.

In the first method, at least one of the first upper electrode and the first lower electrode is preferably made of platinum, at least one of the second upper electrode and the second lower electrode is preferably made of gold, the first etchant is preferably aqua regia, and the second etchant is preferably a potassium hydroxide solution. With this configuration, the resonance frequency of the second piezoelectric resonator is adjusted without variation of the resonance frequency of the first piezoelectric resonator.

A second method for fabricating an RF filter according to the present invention includes the steps of: holding a first piezoelectric resonator and a second piezoelectric resonator on a principal surface of a substrate, the first piezoelectric resonator being constituted by a first piezoelectric film, a first upper electrode and a first lower electrode, the first upper electrode and the first lower electrode being opposed to each other and provided on the upper face and the lower face of the first piezoelectric film, respectively, the second piezoelectric resonator being constituted by a second piezoelectric film, a second upper electrode and a second lower electrode, the second upper electrode and the second lower electrode being opposed to each other and provided on the upper face and the lower face of the second piezoelectric film, respectively; forming a first additional film on a face of at least one of the first upper electrode and the first lower electrode opposite to a face thereof that is in contact with the first piezoelectric film; forming a second additional film on a face of at least one of the second upper electrode and the second lower electrode opposite to a face thereof that is in contact with the second piezoelectric film; adjusting the resonance frequency of the first piezoelectric resonator by using a first etchant that allows etching of the first additional film; and adjusting the resonance frequency of the second piezoelectric resonator by using a second etchant that allows etching of the second additional film.

With the second method for fabricating an RF filter, the resonance frequency of the second piezoelectric resonator can be adjusted without variation of the resonance frequency of the first piezoelectric resonator. Accordingly, complicated masks are unnecessary, so that an RF filter exhibiting a constant frequency characteristic can be easily obtained. Hydrofluoric acid

In the second method, the first additional film is preferably made of silicon nitride, the second additional film is preferably made of silicon oxide, the first etchant is preferably phosphoric acid, and the second etchant is preferably hydrofluoric acid. With this configuration, additional films are formed as intended. In addition, the resonance frequencies of the first and second piezoelectric resonators can be adjusted independently of each other without formation of a mask.

### BRIEF DESCRIPTION OF THE DRAWINGS

FIGS. 1A through 1C are circuit diagrams illustrating an RF filter according to a first embodiment of the present invention.

FIG. 2 is a cross-sectional view illustrating piezoelectric resonators for use in the RF filter of the first embodiment.

FIGS. 3A through 3C are cross-sectional views illustrating respective process steps of fabricating piezoelectric resonators for use in the RF filter of the first embodiment in the order of fabrication.

FIGS. 4A through 4C are cross-sectional views illustrating respective process steps of fabricating piezoelectric resonators for use in the RF filter of the first embodiment in the order of fabrication.

FIG. 5 is a cross-sectional view illustrating another example of piezoelectric resonators for use in the RF filter of the first embodiment.

FIG. 6 is a cross-sectional view illustrating still another example of piezoelectric resonators for use in the RF filter of the first embodiment.

FIG. 7 is a circuit diagram illustrating another example of the RF filter of the first embodiment.

FIG. 8 is a cross-sectional view illustrating piezoelectric resonators for use in an RF filter according to a second embodiment of the present invention.

FIG. 9 is a cross-sectional view illustrating another example of piezoelectric resonators for use in the RF filter of the second embodiment.

### DETAILED DESCRIPTION OF THE INVENTION

### Embodiment 1

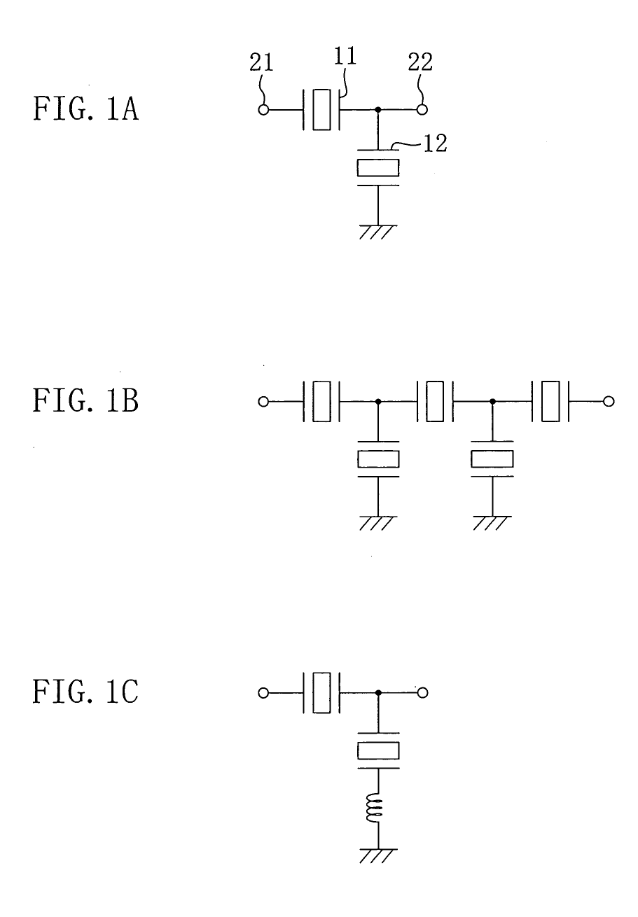

An RF filter and a method for fabricating the RF filter according to a first embodiment of the present invention will be described with reference to the drawings. FIG. 1A illustrates a basic circuit configuration of the RF filter of this embodiment. As shown in FIG. 1A, a ladder filter is constituted by a first piezoelectric resonator 11 that is a serial element connected between an input/output terminal 21 and an input/output terminal 22 and a second piezoelectric resonator 12 that is a parallel element connected between an output terminal 22 and ground.

The resonance frequency of the first piezoelectric resonator 11 as a serial element needs to be adjusted to the maximum frequency in a pass band of the RF filter. The resonance frequency of the second piezoelectric resonator 12 as a parallel element needs to be adjusted to the minimum frequency in the pass band of the RF filter. FIG. 1A illustrates a basic unit of the RF filter in which one first piezoelectric resonator 11 and one second piezoelectric resonator 12 are connected. However, in an actual RF filter, a plurality of basic units shown in FIG. 1A are connected in series.

As shown in FIG. 1B, another first resonator as a serial element may be connected at the end. As shown in FIG. 1C, an inductance 15 may be connected between the second piezoelectric resonator 12 and ground.

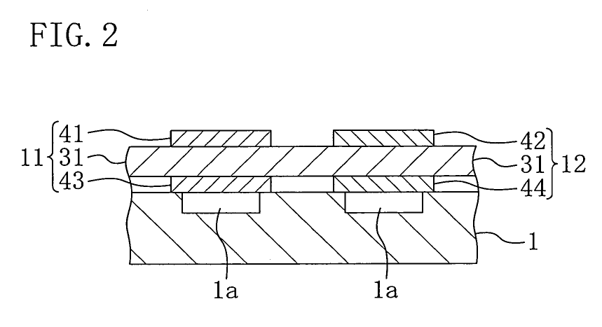

FIG. 2 illustrates cross-sectional structures of piezoelectric resonators for use in the RF filter of the first embodiment. As shown in FIG. 2, a piezoelectric film 31 made of aluminum nitride (AlN) is held above a supporting substrate 1 made of silicon and having two spaced air gaps 1a. A first lower electrode 43 made of a first electrode material is formed on a portion of the lower face of the piezoelectric film 31 located above one of the air gaps 1a. A second lower electrode 44 made of a second electrode material is formed on another portion of the lower face of the piezoelectric film 31 located above the other air gap 1a. A first upper electrode 41 made of the first electrode material is formed on a portion of the upper face of the piezoelectric film 31 opposite to the first lower electrode 43. A second upper electrode 42 made of the second electrode material is formed on another portion of the piezoelectric film 31 opposite to the second lower electrode 44.

Portions of the piezoelectric film 31 above the air gaps 1a are cavity portions that are capable of freely vibrating. The first piezoelectric resonator 11 is constituted by the piezoelectric film 31, the first upper electrode 41 and the first lower electrode 43. The second piezoelectric resonator 12 is constituted by the piezoelectric film 31, the second upper electrode 42 and the second lower electrode 44. Though not shown, the first upper electrode 41, the first lower electrode 43, the second upper electrode 42 and the second lower electrode 44 are provided with interconnection, thereby forming a circuit for the RF filter shown in FIG. 1A.

Though two piezoelectric resonators held on the supporting substrate 1 are shown in FIG. 2, two or more sets of the first piezoelectric resonator 11 and the second piezoelectric resonator 12 may be held. The piezoelectric film 31 is common to all the piezoelectric resonators in this case. Alternatively, a plurality of piezoelectric films 31 are provided for respective piezoelectric resonators.

In the RF filter of this embodiment, the first electrode material is gold (Au) and the second electrode material is titanium (Ti). Accordingly, Au as the first electrode material is etched with an iodine-based etchant whereas Ti as the second electrode material is hardly etched with the iodine-based etchant. On the contrary, Ti is etched with a hydrofluoric acid-based etchant whereas Au is hardly etched by the hydrofluoric acid-based etchant.

Accordingly, wet etching using an iodine-based etchant enables etching of the first upper electrode 41 and the first lower electrode 43, while preventing etching of the second upper electrode 42 and the second lower electrode 44. This allows the resonance frequency of the first piezoelectric resonator 11 to be adjusted with little variation of the resonance frequency of the second piezoelectric resonator 12. On the other hand, wet etching using a hydrofluoric acid-based etchant enables etching of the second upper electrode 42 and the second lower electrode 44, while preventing etching of the first upper electrode 41 and the first lower electrode 43. This allows the resonance frequency of the second piezoelectric resonator 12 to be adjusted with little variation of the resonance frequency of the first piezoelectric resonator 11.

In this manner, it is possible to make the resonance frequencies the first and second piezoelectric resonators 11 and 12 differ from each other without the formation of a mask. As a result, the RF filter is fabricated with ease.

As an iodine-based etchant, it is sufficient to use a mixed solution containing iodine (I) and an alkaline iodide such as potassium iodide (KI) or ammonium iodide (NH₄I). As a hydrofluoric acid-based etchant, it is sufficient to use dilute hydrofluoric acid.

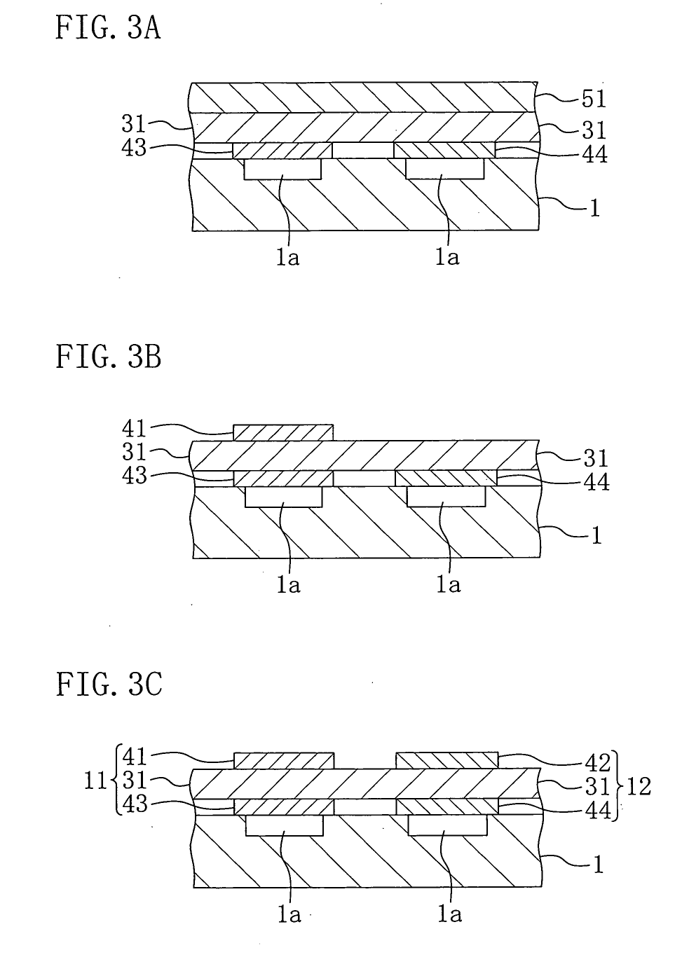

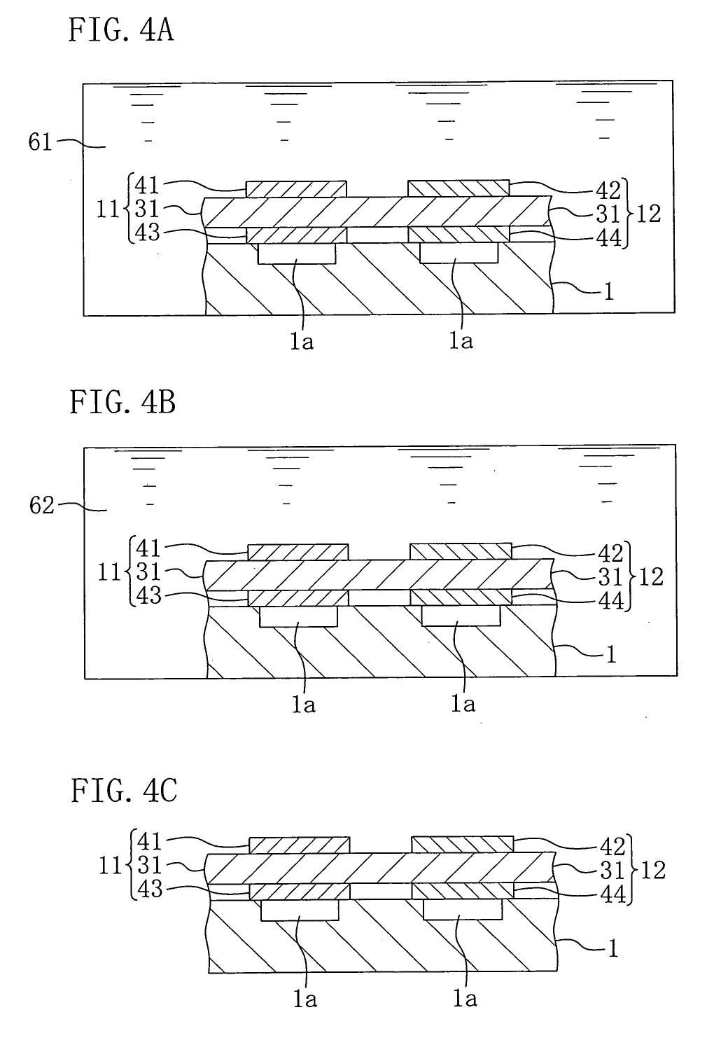

Hereinafter, as an example, process steps of fabricating an RF filter having a band of about 2 GHz will be described with reference to the drawings. FIGS. 3A through 3C and FIGS. 4A through 4C illustrate respective process steps of fabricating an RF filter according to this embodiment in the order of fabrication. First, as shown in FIG. 3A, a piezoelectric film 31 having a thickness of 500 nm and made of aluminum nitride is formed on a temporary substrate 51 made of sapphire or silicon carbide (SiC), for example. Subsequently, a conductive film having a thickness of 230 nm and made of Au is formed on the piezoelectric film 31 and then is patterned, thereby forming a first lower electrode 43. Thereafter, a conductive film having a thickness of 600 nm and made of Ti is formed on the piezoelectric film 31 and then is patterned, thereby forming a second lower electrode 44. Then, a supporting substrate 1 in which air gaps 1a have been formed beforehand and the temporary substrate 51 on which the piezoelectric film 31 has been formed are placed at an appropriate position and then are bonded together.

Next, as shown in FIG. 3B, the temporary substrate 51 is removed. Then, a conductive film having a thickness of 230 nm and made of Au is formed in the exposed surface of the piezoelectric film 31 and then is patterned, thereby forming a first upper electrode 41.

Thereafter, as shown in FIG. 3C, a conductive film having a thickness of 600 nm and made of Ti is formed and then is patterned, thereby forming a second upper electrode 42. In this manner, a first piezoelectric resonator 11 and a second piezoelectric resonator 12 are formed.

Then, as shown in FIG. 4A, wet etching is performed using a first etchant 61 that is a mixed solution containing iodine and potassium iodide with resonance frequencies monitored, thereby adjusting the resonance frequency of the first piezoelectric resonator 11 to the maximum frequency in a pass band of the RF filter.

Subsequently, as shown in FIG. 4B, wet etching is performed using a second etchant 62 that is dilute hydrofluoric acid with the resonance frequencies monitored, thereby adjusting the resonance frequency of the second piezoelectric resonator 12 to the minimum frequency in the pass band of the RF filter. The resonance frequencies may be adjusted in the reverse order.

As shown in FIG. 4C, an unwanted portion of the piezoelectric film 31 may be removed by etching, if necessary. Then, deterioration of a spurious characteristic is prevented even when the distance between adjacent piezoelectric resonators is small.

In this manner, with the method for fabricating an RF filter according to the first embodiment, the first piezoelectric resonator 11 and the second piezoelectric resonator 12 are adjusted to have different resonance frequencies without the use of a mask.

In this embodiment, the first upper electrode 41 and the first lower electrode 43 are made of Au as the first electrode material and the second upper electrode 42 and the second lower electrode 44 are made of Ti as the second electrode material, as an example. Alternatively, the first and second electrode materials only need to be materials that are etched with different etchants. For example, gold (Au) and aluminum (Al) may be used. In such a case, it is sufficient to use an iodine-based etchant as the first etchant 61 and a hydrofluoric acid-based etchant as the second etchant 62.

The first electrode material and the second electrode material may be replaced with each other so that the first upper electrode 41 and the first lower electrode 43 are made of the second electrode material and the second upper electrode 42 and the second lower electrode 44 are made of the first electrode material. The order of adjusting the resonance frequencies may be reversed. That is, after the resonance frequency of the second piezoelectric resonator 12 has been adjusted, the first piezoelectric resonator 11 may be adjusted.

Alternatively, the first electrode material may be a material which is etched with the first etchant 61 but is not etched with the second etchant 62 and the second electrode material may be a material which is etched with the first etchant 61. For example, a combination in which the first electrode material is platinum (Pt), the second electrode material is gold (Au), the first etchant 61 is aqua regia and the second etchant 62 is a potassium hydroxide (KOH) solution may be adopted.

In such a case, first, the resonance frequency of the first piezoelectric resonator 11 is adjusted using the first etchant 61. Then, the resonance frequency of the second piezoelectric resonator 12 is adjusted using the second etchant 62. Though the resonance frequency of the second piezoelectric resonator 12 varies during the adjustment of the resonance frequency of the first piezoelectric resonator 11, this variation causes no problems. This is because the resonance frequency of the second piezoelectric resonator 12 is adjusted at a subsequent step. Instead of a potassium hydroxide solution, a sodium hydroxide solution may be used.

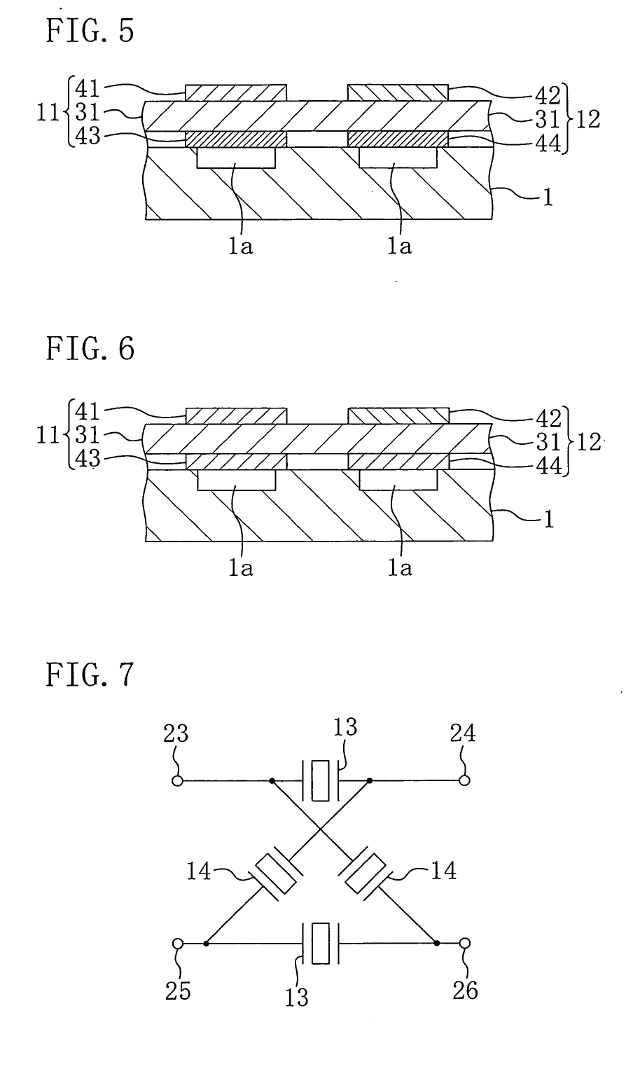

In this embodiment, the first upper electrode 41 and the first lower electrode 43 are made of an identical material and the second upper electrode 42 and the second lower electrode 44 are made of an identical material. In this case, both the upper and lower electrodes are etched in adjusting the resonance frequency. However, in order to adjust the resonance frequency, it is sufficient to adjust the thickness of one of the upper and lower electrodes. Accordingly, as shown in FIG. 5, the first lower electrode 43 and the second lower electrode 44 may be made of a third electrode material which is not etched with any of the first etchant 61 and the second etchant 62.

For example, a combination in which the first lower electrode 43 and the second lower electrode 44 are made of molybdenum (Mo), the first upper electrode 41 is made of gold (Au), the second upper electrode 42 is made of titanium (Ti), the first etchant 61 is an iodine-based etchant and the second etchant 62 is a hydrofluoric acid-based etchant may be adopted. In such a case, three process steps are sufficient for formation of conductive films, so that the fabrication process is simplified. The material for the upper electrode and the material for the lower electrode may be replaced with each other.

In a case where only one of the first upper electrode 41, the first lower electrode 43, the second upper electrode 42 and the second lower electrode 44 is made of a material which is etched with a different etchant, it is also possible to make the resonance frequencies of the first piezoelectric resonator 11 and the second piezoelectric resonator 12 differ from each other without the use of a mask. For example, as shown in FIG. 6, a structure in which the first upper electrode 41, the first lower electrode 43 and the second lower electrode 44 are made of a material which is etched with the first etchant 61 and only the second upper electrode 42 is made of a material which is etched with the second etchant 62 may be adopted.

Specifically, the first upper electrode 41, the first lower electrode 43 and the second lower electrode 44 are made of gold (Au) and the second upper electrode 42 is made of titanium (Ti). In such a case, the first upper electrode 41, the first lower electrode 43 and the second lower electrode 44 are etched with an iodine-based etchant, so that the resonance frequencies of the first and second piezoelectric resonators 11 and 12 are varied. On the other hand, only the second upper electrode 42 is etched with a hydrofluoric acid-based etchant, so that only the resonance frequency of the second piezoelectric resonator 12 is varied.

In this embodiment, the first upper electrode 41 and the first lower electrode 43 constituting the first piezoelectric resonator 11 are made of Au and the second upper electrode 42 and the second lower electrode 44 constituting the second piezoelectric resonator 12 are made of Ti. Since Au is harder and has a lower acoustic impedance than Ti. Accordingly, the insertion loss of the first piezoelectric resonator 11 is smaller than that of the second piezoelectric resonator 12.

It is preferable that the first piezoelectric resonator 11 exhibiting a smaller insertion loss is a serial element connected in series with other piezoelectric resonators and placed between the input/output terminal 21 and the input/output terminal 22 and the second piezoelectric resonator 12 is a parallel element connected in parallel with other piezoelectric resonators and placed between the input/output terminal 21 and the input/output terminal 22. Then, the total insertion loss of the RF filter can be reduced.

In this embodiment, the RF filter is a ladder filter. Alternatively, an RF filter of a lattice type as shown in FIG. 7 may be adopted. Then, similar advantages are also obtained. In such a case, the resonance frequencies of piezoelectric resonators 13 connected between an input/output terminal 23 and an input/output terminal 24 and between an input/output terminal 25 and an input/output terminal 26, respectively, are adjusted to the maximum frequency in a pass band, and the resonance frequencies of piezoelectric resonators 14 connected between the input/output terminal 23 and the input/output terminal 26 and between the input/output terminal 25 and the input/output terminal 24, respectively, are adjusted to the minimum frequency in the pass band.

A piezoelectric resonator which is made of a harder electrode material having a lower acoustic impedance and exhibits a small insertion loss is preferably used as each of the piezoelectric resonators 13 connected between input/output terminals with an identical polarity. This is because the total insertion loss of the RF filter is reduced in this case.

In this embodiment, the piezoelectric film is bonded to the supporting substrate having air gaps so that the piezoelectric film has cavity portions. Alternatively, the lower electrodes may have projections so that cavities are formed under the piezoelectric film. The piezoelectric resonators may be formed by using a sacrificial layer, instead of bonding. The piezoelectric resonators may have an acoustic multilayer film, instead of air gaps.

### Embodiment 2

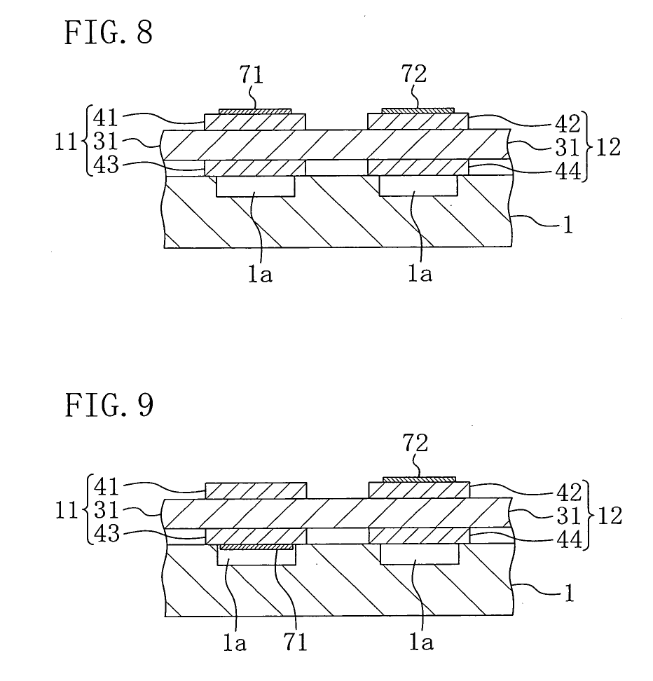

Hereinafter, an RF filter and a method for fabricating the RF filter according to a second embodiment of the present invention will be described with reference to the drawings. FIG. 8 illustrates cross-sectional structures of piezoelectric resonators for use in the RF filter of the second embodiment. In FIG. 8, components also shown in FIG. 2 are denoted by the same reference numerals, and the description thereof will be omitted.

The RF filter of the second embodiment is a ladder filter similar to that of the first embodiment and has the same circuit configuration as that shown in FIG. 1A.

As shown in FIG. 8, in this embodiment, each of a first upper electrode 41, a first lower electrode 43, a second upper electrode 42 and a second lower electrode 44 has a thickness of 400 nm and made of molybdenum (Mo). A first additional film 71 made of a first material is formed on the first upper electrode 41. A second additional film 72 made of a second material is formed on the second upper electrode 42.

The first and second materials only need to be materials which are etched with different etchants. In this embodiment, the first material is silicon nitride (SiN) and the thickness of the first additional film 71 is 200 nm. The second material is silicon dioxide (SiO₂) and the thickness of the second additional film 72 is 200 nm.

The first additional film 71 made of SiN is etched with phosphoric acid but the second additional film 72 made of SiO₂ is hardly etched with phosphoric acid. On the other hand, the second additional film 72 made of SiO₂ is etched with hydrofluoric acid but the first additional film 71 made of SiN is hardly etched with hydrofluoric acid.

Accordingly, when the first additional film 71 is wet etched using phosphoric acid as a first etchant 61, the resonance frequency of a first piezoelectric resonator 11 is adjusted to the maximum frequency in a pass band of the RF filter with little variation of the resonance frequency of a second piezoelectric resonator 12.

In addition, when the second additional film 72 is wet etched using hydrofluoric acid as a second etchant 62, the resonance frequency of the second piezoelectric resonator 12 is adjusted to the minimum frequency in the pass band of the RF filter with little variation of the resonance frequency of the first piezoelectric resonator 11. In this manner, the resonance frequency can be adjusted even in a structure in which etching is performed not on the electrodes themselves but on the additional films formed on the electrodes.

The first material and the second material may be replaced with each other. Specifically, the first additional film 71 may be made of SiN and the second additional film 72 may be made of SiO₂. After adjustment of the resonance frequency of the second resonator 12, the resonance frequency of the first resonator 11 may be adjusted.

The additional films are not limited to insulating films. The first material may be platinum (Pt) and the second material may be gold (Au), for example. In such a case, it is sufficient that the first etchant 61 is aqua regia and the second etchant 62 is a potassium hydroxide solution, as in the first embodiment.

Additional films are not necessarily formed on the upper electrodes but may be formed on the lower electrodes or on all the electrodes. As shown in FIG. 9, a structure in which an additional film is formed on the upper electrode of one of the piezoelectric resonators and an additional film is formed on the lower electrode of the other piezoelectric resonator may be adopted. Alternatively, the resonance frequency of one of the piezoelectric resonators may be adjusted by etching the electrode itself and the resonance frequency of the other piezoelectric resonator may be adjusted by etching the additional film.

In the second embodiment, if a material which is harder and has a lower acoustic impedance is used for an additional film formed on an electrode constituting a piezoelectric resonator serving as a serial element, the total insertion loss of the RF filter is reduced.

In the case of forming a lattice filter as shown in FIG. 7, similar advantages are also obtained.

As described above, according to the present invention, an RF filter in which piezoelectric resonators formed on a substrate are adjusted to have different resonance frequencies without complicated process steps is implemented. Therefore, the present invention is useful for RF filters using piezoelectric resonators and methods for fabricating the filters.

What is claimed is:

1. An RF filter, comprising:
a substrate having a principal surface;
one or more first piezoelectric resonators, each of the first piezoelectric resonators being held on the principal surface of the substrate and being constituted by a first piezoelectric film, a first upper electrode and a first lower electrode, the first upper electrode and the first lower electrode being opposed to each other and provided on the upper face and the lower face of the first piezoelectric film, respectively; and
one or more second piezoelectric resonators, each of the second piezoelectric resonators being held on the principal surface of the substrate, being constituted by a second piezoelectric film, a second upper electrode and a second lower electrode, and having a resonance frequency different from that of each of the first piezoelectric resonators, the second upper electrode and the second lower electrode being opposed to each other and provided on the upper face and the lower face of the second piezoelectric film, respectively,
wherein at least one of the first upper electrode and the first lower electrode is made of a first electrode material and at least one of the second upper electrode and the second lower electrode is made of a second electrode material.

2. The RF filter of claim 1, wherein the first electrode material is etched with a first etchant and has etching resistance to a second etchant that allows etching of the second electrode material.

3. The RF filter of claim 2, wherein the first electrode material is platinum, and
the second electrode material is gold.

4. The RF filter of claim 2, wherein the second electrode material has etching resistance to the first etchant.

5. The RF filter of claim 4, wherein the first electrode material is gold, and
the second electrode material is titanium or aluminum.

6. The RF filter of claim 1, further comprising at least one of a first additional film and a second additional film, the first additional film being formed on at least one of the upper face of the first upper electrode and the lower face of the first lower electrode, the second material being formed on at least one of the upper face of the second upper electrode and the lower face of the second lower electrode.

7. The RF filter of claim 1, wherein one of the second upper electrode and the second lower electrode is electrically connected to the first upper electrode or the first lower electrode to form a basic unit of a ladder filter in which the other of the second upper electrode and the second lower electrode is grounded, and
the first electrode material and the second electrode material are selected so that an insertion loss of each of the first piezoelectric resonators is smaller than that of each of the second piezoelectric resonators.

8. The RF filter of claim 7, wherein an inductor is electrically connected between the second upper electrode or the second lower electrode and ground.

9. The RF filter of claim 1, further comprising a first input/output terminal, a second input/output terminal, a third input/output terminal and a fourth input/output terminal,
wherein the number of the first resonators is two,
one of the two first resonators is electrically connected between the first input/output terminal and the second input/output terminal,
the other first resonator is electrically connected between the third input/output terminal and the fourth input/output terminal,
the number of the second resonators is two,
one of the two second resonators is electrically connected between the first input/output terminal and the fourth input/output terminal,
the other second resonator is electrically connected between the third input/output terminal and the second input/output terminal, and
the first electrode material and the second electrode material are selected so that an insertion loss of each of the first resonators is smaller than that of each of the second resonators.

10. An RF filter, comprising:
a substrate having a principal surface;
one or more first piezoelectric resonators, each of the first piezoelectric resonators being held on the principal surface of the substrate and being constituted by a first piezoelectric film, a first upper electrode and a first lower electrode, the first upper electrode and the first lower electrode being opposed to each other and provided on the upper face and the lower face of the first piezoelectric film, respectively;
one or more second piezoelectric resonators, each of the second piezoelectric resonators being held on the principal surface of the substrate, being constituted by a second piezoelectric film, a second upper electrode and a second lower electrode, and having a resonance frequency different from that of each of the first piezoelectric resonators, the second upper electrode and the second lower electrode being opposed to each other and provided on the upper face and the lower face of the second piezoelectric film, respectively;
at least one of a first upper-electrode additional film and a first lower-electrode additional film, the first upper-electrode additional film being formed on the upper face of the first upper electrode, the first lower-electrode additional film being formed on the lower face of the first lower electrode; and
at least one of a second upper-electrode additional film and a second lower-electrode additional film, the second upper-electrode additional film being formed on the upper face of the second upper electrode, the second lower-electrode additional film being formed on the lower face of the second lower electrode,
wherein at least one of the first upper-electrode additional film and the first lower-electrode additional film is made of a first additional-film material, and
at least one of the second upper-electrode additional film and the second lower-electrode additional film is made of a second additional-film material.

11. The RF filter of claim 10, wherein the first additional-film material is etched with a first etchant and has etching resistance to a second etchant that allows etching of the second additional-film material.

12. The RF filter of claim 11, wherein the first additional-film material is platinum, and
the second additional-film material is gold.

13. The RF filter of claim 11, wherein the second additional-film material has etching resistance to the first etchant.

14. The RF filter of claim 13, wherein the first additional-film material is silicon nitride, and
the second additional-film material is silicon oxide.

15. The RF filter of claim 13, wherein the first additional-film material is gold, and
the second additional-film material is titanium or aluminum.

16. The RF filter of claim 10, wherein one of the second upper electrode and the second lower electrode is electrically connected to the first upper electrode or the first lower electrode to form a basic unit of a ladder filter in which the other of the second upper electrode and the second lower electrode is grounded, and
the first additional-film material and the second additional-film material are selected so that an insertion loss of each of the first piezoelectric resonators is smaller than that of each of the second piezoelectric resonators.

17. The RF filter of claim 10, wherein an inductor is electrically connected between the second upper electrode or the second lower electrode and ground.

18. The RF filter of claim 10, further comprising a first input/output terminal, a second input/output terminal, a third input/output terminal and a fourth input/output terminal,
wherein the number of the first resonators is two,
one of the two first resonators is electrically connected between the first input/output terminal and the second input/output terminal,
the other first resonator is electrically connected between the third input/output terminal and the fourth input/output terminal,
the number of the second resonators is two,
one of the two second resonators is electrically connected between the first input/output terminal and the fourth input/output terminal,
the other second resonator is electrically connected between the third input/output terminal and the second input/output terminal, and
the first additional-film material and the second additional-film material are selected so that an insertion loss of each of the first resonators is smaller than that of each of the second resonators.

19. A method for fabricating an RF filter, the method comprising the steps of:
holding a first piezoelectric resonator and a second piezoelectric resonator on a principal surface of a substrate, the first piezoelectric resonator being constituted by a first piezoelectric film, a first upper electrode and a first lower electrode, the first upper electrode and the first lower electrode being opposed to each other and provided on the upper face and the lower face of the first piezoelectric film, respectively, the second piezoelectric resonator being constituted by a second piezoelectric film, a second upper electrode and a second lower electrode, the second upper electrode and the second lower electrode being opposed to each other and provided on the upper face and the lower face of the second piezoelectric film, respectively;
adjusting the resonance frequency of the first piezoelectric resonator by using a first etchant that allows etching of at least one of the first upper electrode and the first lower electrode; and
adjusting the resonance frequency of the second piezoelectric resonator by using a second etchant that allows etching of at least one of the second upper electrode and the second lower electrode.

20. The method of claim 19, wherein at least one of the first upper electrode and the first lower electrode is made of gold,
at least one of the second upper electrode and the second lower electrode is made of titanium or aluminum,
the first etchant is an iodine-based etchant, and
the second etchant is a hydrofluoric acid-based etchant.

21. The method of claim 19, wherein at least one of the first upper electrode and the first lower electrode is made of platinum,
at least one of the second upper electrode and the second lower electrode is made of gold,
the first etchant is aqua regia, and
the second etchant is a potassium hydroxide solution

22. A method for fabricating an RF filter, the method comprising the steps of:
holding a first piezoelectric resonator and a second piezoelectric resonator on a principal surface of a substrate, the first piezoelectric resonator being constituted by a first piezoelectric film, a first upper electrode and a first lower electrode, the first upper electrode and the first lower electrode being opposed to each other and provided on the upper face and the lower face of the first piezoelectric film, respectively, the second piezoelectric resonator being constituted by a second piezoelectric film, a second upper electrode and a second lower electrode, the second upper electrode and the second lower electrode being opposed to each other and provided on the upper face and the lower face of the second piezoelectric film, respectively;
forming a first additional film on a face of at least one of the first upper electrode and the first lower electrode opposite to a face thereof that is in contact with the first piezoelectric film;
forming a second additional film on a face of at least one of the second upper electrode and the second lower electrode opposite to a face thereof that is in contact with the second piezoelectric film;
adjusting the resonance frequency of the first piezoelectric resonator by using a first etchant that allows etching of the first additional film; and
adjusting the resonance frequency of the second piezoelectric resonator by using a second etchant that allows etching of the second additional film.

23. The method of claim 22, wherein the first additional film is made of silicon nitride,
the second additional film is made of silicon oxide,
the first etchant is phosphoric acid, and
the second etchant is hydrofluoric acid.
